(19) United States
(12) Patent Application Publication
(10) Pub. No.: US 2017/0192066 A1
(43) Pub. Date: Jul. 6, 2017

(54) MAGNETOMETRIC SENSOR

(71) Applicant: THALES, Courbevoie (FR)

(72) Inventors: Emmanuel Desurvire, Palaiseau (FR); Jean-Paul Castera, Palaiseau (FR); Bertrand Demotes-Mainard, Neuilly-sur-Seine Cedex (FR)

(21) Appl. No.: 15/314,556

(22) PCT Filed: May 29, 2015
(86) PCT No.: PCT/EP2015/062039

§ 371 Date: Nov. 29, 2016

(30) Foreign Application Priority Data
May 30, 2014 (FR) 1401252

(51) Int. Cl. G01R 33/00; G01R 33/035

(52) U.S. Cl. CPC G01R 33/0041; G01R 33/035; G01R 33/0047

(57) ABSTRACT

This sensor (10) includes a magnetic sensor (12) generating a response signal (V) when it is immersed in an external magnetic field (Bₑₓₜ) generating an external flux (φₑₓₜ) through said sensor. This sensor includes: a control circuit (14) taking as an input the response signal of the sensor and generating at the output a feedback current (i_{CR}); and a conductive wire (16) positioned in the vicinity of the sensor and connected to the output of the control circuit, the wire being crossed by the feedback current, the circuit and the conductive wire being such that a feedback magnetic field (B_{CR}) is generated, the flux of which through the sensor substantially compensates, at each instant, for the external flux, an output signal of the sensor being formed by the feedback current.

The field of the invention is that of magnetometric sensors, and more particularly that of differential magnetometric sensors for measuring alternating magnetic fields or more generally magnetic fields which vary overtime.

A magnetometric sensor includes a component sensitive to the magnetic field, called a magnetic sensor in the present document, which is able to issue, as a voltage or a current, a measurement signal corresponding to the external magnetic field Bₑₓₜ in which it is immersed.

Presence of magnetometric sensors have a limited frequency range of use or band width. This is due to the impedance of the measurement circuit placed downstream from the magnetic sensor.

The widening of the band width of magnetometric sensors is a general problem of this technical field. In order to circumvent this problem, it is considered that the useful area of a magnetometric sensor is in principle limited and it is simply sought to optimize its band width by acting on the value of the impedance of the measurement circuit.

Moreover, known magnetic sensors have a response signal which is not linear with the magnetic field to be measured.

From among magnetic sensors, optical magnetic sensors are known such as sensors with diamond N-V centers, in which the transition between two energy levels of the electrons of an atom forming an impurity in a crystal is modified when this crystal is immersed in an external magnetic field Bₑₓₜ. The modification of the transition modifies the response of the crystal illuminated by a suitable laser light. A magnetic sensor operates at room temperature.

The response of the crystal is linear but on a reduced frequency range around a characteristic frequency of the transition used.

From among magnetic sensors, superconducting magnetic sensors are also known, which are of particular interest, since they provide the highest physically attainable sensitivities. Such a magnetic sensor, applying superconducting materials, operates at low temperatures, around about 80 K, for so called critical high temperature superconducting materials, or ultra-low temperature superconducting materials, around about one milli-Kelvin for so called low critical temperature superconducting materials.

A superconducting magnetic sensor is a SQUID (“Superconducting QUantumInterference Device”) component or a SQIF (“Superconducting Quantum Interference Filter”) component. A SQIF component consists of a matrix of SQUID components, connected in series, in parallel or both.

Because of their operating principles, the SQUID and SQIF components have a non-linear response, i.e. the voltage V(φ) induced by the flux φ of the external magnetic field Bₑₓₜ crossing a surface S of the component, is not a linear function of the flux φₑₓₜ, and accordingly of the external magnetic field Bₑₓₜ.

In the case of a SQUID component, this response is a sign wave. In the region of the inflection point of the sign wave, the behavior to the first order is linear. However, this region corresponds to a relatively narrow flux range.

In the case of a SQIF component, the response is uniform, V(φ)=cste, except around certain characteristic points, periodically positioned, for which the flux φₑₓₜ of the external magnetic field Bₑₓₜ is equal to an integer number of times of a characteristic flux φ₀, a so called <<fluxon>>. Thus, the response of a SQIF component assumes the shape of an <<inverted comb>>.

In a modified SQIF component, having a particular configuration, the response is uniform except in a region around the origin, φₑₓₜ=0, wherein this response cancels out. However, this region corresponds to a relatively narrow flux range.

In order to utilize the sensitivity of a superconducting magnetic sensor, one should resort to the linear domain, which is however reduced to narrow regions.

Thus, even if the magnetic sensors are very sensitive, their main defect therefore remains in their very small band width.

Therefore the object of the invention is to overcome these problems.

The invention is notably relative to a magnetometric sensor having both an extended sensitivity range and a linear response.

For this purpose, the object of the invention is a magnetometric sensor including a magnetic sensor having a surface and generating a response signal when it is immersed in an external magnetic field generating an external flux through said surface, characterized in that it includes: a control circuit taking as an input the response signal of the magnetic sensor and generating at the output a feedback current; and a conductive wire positioned in the vicinity of the magnetic sensor and connected to the output of the control circuit, the wire being crossed by the feedback current, the circuit and the conductive wire being such that a feedback magnetic field is generated, the feedback flux of which through the surface of the magnetic sensor substantially compensates, at each instant, for the external flux, an output signal of the magnetometric sensor being formed by the feedback current.

According to particular embodiments, the magnetometric sensor includes one or several of the following features, taken individually or according to all the technically possible combinations:
the magnetometer is a superconducting magnetometer.
as the external magnetic field is variable overtime, the output signal of the magnetometric sensor is a measurement of the external magnetic field.
the output signal of the magnetometric sensor is a linear measurement of the external magnetic field.
the surface of the magnetic sensor is planar and in which the conductive wire is substantially placed in the plane of the surface.
the control circuit includes a means for comparing the response signal of the magnetic sensor with a reference signal able to generate a comparison signal, and a current source controlled by the comparison signal and able to generate the feedback current.
the magnetic sensor consists of a plurality of elementary magnetic sensors connected in series between two input terminals of the control circuit.
the conductive wire is configured in order to form at least one loop.
the loop includes a plurality of turns.
the conductive wire is configured in order to form at least one meander between two neighboring elementary magnetometers.
the sensor includes a case delimiting a cavity isolated from parasitic magnetic perturbations and inside which is housed the magnetic sensor and the conductive wire.

The invention and advantages thereof will be better understood upon reading the description which follows of embodiments and of methods for use, exclusively given as an example and made with reference to the appended drawings wherein:

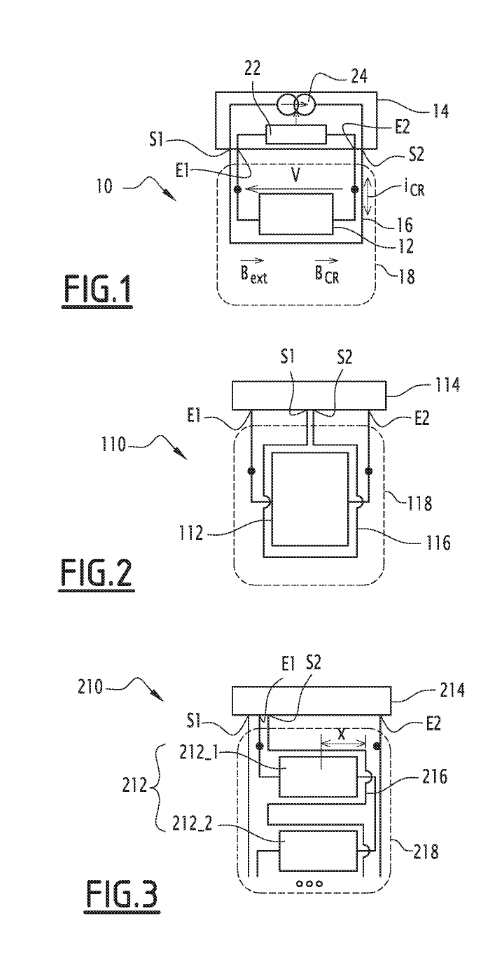

FIG. 1 is an illustration of the principle of a magnetometric sensor according to the invention;

FIG. 2 is a schematic illustration of a so called loop embodiment of the sensor of FIG. 1; and,

FIG. 3 is a schematic illustration of a so called meander embodiments of the sensor of FIG. 1;

The magnetometric sensor according to the invention is illustrated in FIG. 1.

It has the function of allowing an instantaneous measurement of an external magnetic field Bₑₓₜ(t), which varies overtime t.

The magnetometric sensor 10 includes a magnetic sensor 12, a control circuit 14 and a conductive wire 16.

Advantageously, the magnetometric sensor 10 includes a casing interiorly delimiting a cavity in which are housed at least the magnetic sensor 12 and the conductive wire 16, and optionally the control circuit 14. The cavity, generally referenced with number 18 in FIG. 1, corresponds to the volume in which prevails the magnetic field to be measured, this volume being isolated, by the case from any other parasitic magnetic influence or perturbation. The material in which is formed the casing is therefore suitable for isolating the cavity from parasitic magnetic fields.

The magnetic sensor 12 is preferably a superconducting magnetic sensor.

The magnetic sensor 12 is of a rectangular parallelepipedal shape. It has a small thickness and an active surface S, substantially plane and having a normal in the direction of the thickness of the magnetic sensor.

The magnetic sensor 12 is able to generate, between both of its output terminals, a response signal, which here is a voltage V. The voltage V is a function of the instantaneous total magnetic flux φ(t) through the surface S.

The control circuit 14 receives between both of its input terminals E1 and E2, the response signal V(φ(t))produced by the magnetic sensor 12, and generates a feedback current i_{CR}(t) between both of its output terminals S1 and S2.

More specifically, the control circuit 14 includes a comparison means 22 including two input terminals, connected to the output terminals of the magnetic sensor 12, and able to compare the response signal V(φ(t)) with a reference signal V₀ and to generate a comparison signal.

The control circuit 14 includes a current source 24 controlled by the comparison signal and able to generate, between two output terminals, the feedback current i_{CR}(t).

The conductive wire 16 is connected between the output terminals of the control circuit 14. It is conformed in order to circulate in the vicinity of the magnetic sensor 12. The conductive wire 16 is crossed by the feedback current i_{CR}(t). Consequently, it generates around it a feedback magnetic field B_{CR}(t). The field B_{CR}(t) is linear with respect to the current i_{CR}(t) It generates a feedback flux φ_{CR}(t) through the surface S of the magnetic sensor: φ_{CR}(t)=B_{CR}(t).S

At each instant, the response signal V(t) issued by the magnetic sensor 12 depends on the total magnetic flux φ(t) crossing the surface S.

This total flux φ(t) is the sum of an external flux φₑₓₜ(t), which results from the external magnetic field Bₑₓₜ(t) to be measured according to the relationship φₑₓₜ(t)=Bₑₓₜ(t).S, and from the feedback flux φ_{CR}(t).

The sensor 10 is balanced when the total flux φ(t) received by the magnetic sensor 12 is constant. Under these conditions, permanently forced by the instantaneous feedback, the feedback current i_{CR}(t) represents a linear measurement of the external magnetic field Bₑₓₜ(t)

In order that this balance exists, the geometrical and physical parameters of the sensor 10 are selected so that the feedback flux is opposed to the external flux and that the response V(t) of the magnetic sensor 12 may be instantaneously reduced to the level of the reference voltage V₀. In other words, the control circuit 14 and the conductive wire 16 are such that a feedback magnetic field is generated, the flux of which through the active surface of the magnetic sensor substantially compensates at each instant, for the flux of the external magnetic field.

It should be noted that if the external magnetic field Bₑₓₜ has a DC component, the stabilization point will be the reference voltage V₀ shifted by a constant. This constant may be canceled out by the feedback current i_{CR}, by applying a bias on the reference voltage V₀.

By suitably selecting the reference voltage V₀, the maximum sensitivity of the sensor 10 is obtained for a response area of the magnetic sensor wherein the derivative ≢V/≢φ is a maximum.

It should be emphasized that in the magnetometric sensor 10, the response signal of the magnetic sensor is not considered as a measurement signal, but as a signal for regulating a feedback loop. This is the feedback signal which is the measurement signal.

In FIG. 2, is illustrated a sensor 110 which is a first preferred embodiment of the sensor shown above in a generic way.

In the sensor 110, the conductive wire 116 is configured so as to form a loop around the magnetic sensor 112. The wire 116 is substantially located in the plane P of the surface S of the magnetic sensor 112.

The loop may include N turns, which gives the possibility of increasing the feedback flux for a same amplitude of the feedback current.

This loop configuration has a wide band response.

The band width is limited to the high frequencies mainly by a radiative resistance effect, R_{rad}, which is proportional to f⁴, wherein f is the frequency of the feedback current i_{CR}. The radiative resistance supersedes here another limitation which is due to the inductance of the loop formed by the wire 116, this inductance being proportional to f.

By reducing the dimensions of the circuit formed by the conductive wire 116, the radiative resistance R_{rad} may be reduced so as to push forward at the most the high cutoff frequency of the sensor 110.

This loop configuration allows dense one-dimensional or two-dimensional integration into the plane P.

This loop configuration gives the possibility of producing a magnetic sensor with reduced dimensions.

In FIG. 3, is illustrated a sensor 210 which is a second preferred embodiment of the sensor shown in FIG. 1 in a generic way.

In this second embodiment, a so called meander configuration, the magnetic sensor 212 consists of a plurality of elementary magnetic sensors 212-i, which are positioned along a row, so that their surfaces Si are in the same plane P, and which are connected in series between the input terminals E1 and E2 of the control circuit 14.

The conductive wire 216 is configured so as to circulate between two elementary magnetic sensors 212-i so as to form a plurality of meanders. The elementary sensors 212-i are placed in one meander out of two so that the flux of the feedback magnetic field generated by the wire 216 always has the same sign and may compensate for the external magnetic field to be measured.

In this embodiment, the elementary magnetic sensors 212-i are asymmetrical (their response being such that: V(−100 )=−V(φ), or symmetrical (their response being such that: V(−φ)=V(φ)).

The meander configuration is characterized by an inductance and a radiative resistance which are intrinsically smaller than that of the loop configuration, which gives the possibility of pushing further forward the high cutoff frequency of the bandwidth of the sensor 210.

There again, by selecting very small dimensions for the circuit formed by the wire 216, the radiative resistance may be reduced so as to further push forward at most the high cutoff frequency of the sensor.

Further, it is possible to optimize the geometrical parameters, for example, the distance x between the wire 216 and the axis of the magnetic sensors may be increased. The magnetic field generated by a wire decreasing as 1/x, in order to obtain the same feedback flux, the feedback current has to be increased. This has the advantage of allowing detection of external magnetic fields of very low amplitude (along the normal to the surface Si of the magnetic sensors), by using the high intensity feedback current.

This meander configuration allows one-dimensional or two-dimensional dense integration into the plane P. Indeed, by using symmetrical elementary magnetic sensors (such as for example superconducting magnetic sensors of the SQIF type), the response of which is independent of the direction of the magnetic field, it is possible to place elementary magnetic sensors 212-I in each of the meanders defined by the wire 216. The surface density of elementary magnetic sensors may thereby be increased, which, at constant surface of the component, gives the possibility of increasing the sensitivity of the magnetometer of the latter.

This loop configuration gives the possibility of producing a magnetic sensor wih reduced dimensions.

The meander configuration is moreover more advantageous than the loop configuration, since it is simpler to optimize and to integrate at a large scale.

The magnetometric sensor shown above has a wide band width on which, when the magnetic sensor is of the superconducting type, it has a very high magnetometric sensitivity. By suitable design of the magnetometric sensor, it is possible to contemplate a band width extending from very low frequencies VLF, to ultra-high frequencies UHF, i.e. between about a few kHz and about 1,000 MHz.

The magnetometric sensor shown above also has a linear response relatively to the amplitude of the external magnetic field to be measured, which is uniform over the whole band width.

In terms of intensity of the measurable external magnetic field, the magnetometric sensor may be adapted: segmentation into feedback current domains of the control circuit, optimized dimensioning of the loop/meander circuit, multi-scale integration, etc.

Optionally, low-pass filters may be introduced into the control circuit, in order to allow specification of a certain number of frequency ranges of use, or by order of the frequency magnitude of the external magnetic field to be measured, or by frequency domains of interest.

The magnetometric sensor finally provides the possibility of a high-density planar integration.

1. A magnetometric sensor including a magnetic sensor having a surface and generating a response signal when it is immersed in an external magnetic field which generates an external flux through said surface, wherein the magnetometric sensor includes:
a control circuit taking at an input the response signal of the magnetic sensor and generating at an output a feedback current; and,
a conductive wire positioned in a vicinity of the magnetic sensor and connected to the output of the control circuit, the conductive wire being crossed by the feedback current,
the control circuit and the conductive wire being such that a feedback magnetic field is generated, a feedback flux thereof through the surface of the magnetic sensor substantially compensates at each instant for the external flux,
an output signal of the magnetometric sensor being formed by the feedback current.

2. The magnetometric sensor according to claim 1, wherein the magnetic sensor is a superconducting magnetometer.

3. The magnetometric sensor according to claim 1, wherein the external magnetic field being variable overtime, the output signal of the magnetometric sensor is a measurement of the external magnetic field.

4. The magnetometric sensor according to claim 1, wherein the output signal of the magnetometric sensor is a linear measurement of the external magnetic field.

5. The magnetometric sensor according to claim 1, wherein the surface of the magnetic sensor is planar and wherein the conductive wire is placed substantially in the plane of said surface.

6. The magnetometric sensor according to claim 1, wherein the control circuit includes a comparison means comparing the response signal of the magnetic sensor relatively to a reference signal and generating a comparison signal, and a current source controlled by the comparison signal and generating the feedback current.

7. The magnetometric sensor according to claim 1, wherein the magnetic sensor consists of a plurality of elementary magnetic sensors connected in series between two input terminals of the control circuit.

8. The magnetometric sensor according to claim 1, wherein the conductive wire is configured for forming at least one loop.

9. The magnetometric sensor according to claim 8, wherein the loop includes a plurality of turns.

10. The magnetometric sensor according to claim 7, wherein the conductive wire is configured in order to form at least one meander between two neighboring elementary magnetic sensors.

11. The magnetometric sensor according to claim 1, including a case delimiting a cavity isolated from parasitic magnetic perturbations and inside which is housed the magnetic sensor and the conductive wire.
